(19) United States
(12) Patent Application Publication
(10) Pub. No.: US 2010/0154885 A1
(43) Pub. Date: Jun. 24, 2010

(54) THIN FILM SOLAR CELL AND MANUFACTURING METHOD THEREOF

(76) Inventor: Chien-Pang YANG, Houli Township (TW)

Correspondence Address: SINORICA, LLC, 2275 Research Blvd., Suite 500, ROCKVILLE, MD, 20850, US

(21) Appl. No.: 12/639,174

(22) Filed: Dec. 16, 2009

(30) Foreign Application Priority Data
Dec. 19, 2008 (TW) 097149594

(51) Int. Cl. H01L 31/0272; H01L 31/18

(52) U.S. Cl. 136/256; 438/84; 257/E31.027

(57) ABSTRACT

The invention discloses a thin film solar cell and the manufacturing method thereof. The thin film solar cell comprises a substrate, a back electrode layer, an absorber layer, a buffer layer, and a transparent electrode layer. The buffer layer is a compound consisted essentially of a metal and at least two elements of Group VIA. The compound has a chemical formula of Mₓ (VIA1_{y}, VIA2_{z})_{w}. M represents a singular metal element or an alloy of multiple metal elements, and VIA1 and VIA2 are two different elements of Group VIA. X, y, z and w are non-zero positive numbers. The buffer layer has a band gap gradient between the absorber layer and the transparent electrode layer.

### BACKGROUND OF THE INVENTION

1. Technical Field

The present invention relates to a thin film solar cell and the manufacturing method thereof, in particular, relating to a thin film solar cell has a buffer layer of a compound consisting essentially of a metal and two different elements of Group VIA and the manufacturing method thereof.

2. Description of Related Art

According to current thin film solar cell technology, thin film solar cells based on semiconductors layers of copper indium gallium diselenide (abbreviated as CIGS) are one of the most efficient solar cells of today. Formerly, the predecessor of the CIGS thin film solar cells consisted essentially of copper (Cu), indium (In), and selenium (Se) and is therefore known as the CIS (CuInSe₂, copper indium diselenide) thin film solar cell. It was not until gallium (Ga) or sulfur (S) was subsequently incorporated into the CIS thin film solar cells that the CIGS thin film solar cells, which deliver higher conversion efficiency than the CIS version, were produced. Nowadays, CIGS solar cells are mass-produced mainly by a vacuum-based process. In addition, a CIGS solar cell often requires a buffer layer, typically a cadmium sulfide (CdS) layer, because the operation of a CIGS solar cell depends chiefly on photoelectric conversion taking place at the heterojunction between the n-type cadmium sulfide layer and a p-type absorber layer.

However, the method for making the foregoing CIGS thin film solar cell requires that the absorber layer be formed by selenization. The process is that depositing copper, gallium, indium and selenium from the precursors of copper, gallium, indium and selenium, then followed by selenization to form a semi-product having CIGS absorber layer. A buffer layer is then formed on this semi-product via chemical bath deposition (CBD). In the CBD process, it is to utilize one salt of zinc, cadmium or indium, and a precursor of sulfur or selenium. Dissolving both in a water solution and adjust the pH value of the water solution. Thereby, the buffer layer is formed.

The buffer layer formed via the above-mentioned process is made from a singular material, which will cause the band gap discontinuity. Also, the cadmium sulfide (CdS) layer serving as the buffer layer contains cadmium (Cd), which is a poisonous substance and may lead to pollution during use.

### SUMMARY OF THE INVENTION

To overcome the shortcomings of the prior arts mentioned above, the present invention provides a thin film solar cell. The thin film solar cell comprises a substrate, a back electrode layer, an absorber layer, a buffer layer, and a transparent electrode layer. These layers are formed on the substrate and deposited serially. The buffer layer is a compound consisting essentially of a metal and two different elements of Group VIA. The compound has a chemical formula of Mₓ(VIA1_{y}, VIA2_{z})_{w}. M represents a singular metal element or an alloy of multiple metal elements, and VIA1 and VIA2 are two different elements of Group VIA. X, y, z, w are non-zero positive numbers. The buffer layer has a band gap gradient between the absorber layer and the transparent electrode layer.

Therefore, the primary object of the present invention is to provide a thin film solar cell which has a buffer layer. The buffer layer is a compound which is essentially consisted of a metal and two different elements of Group VIA. The buffer layer has a band gap gradient between the absorber layer and the transparent electrode layer and the wavelength range of light utilized by the thin film solar cell is widened.

Another object of the present invention is to provide a thin film solar cell which has a buffer layer. The buffer layer is a compound which is essentially consisted of a metal and two different elements of Group VIA. A band gap gradient is formed between the absorber layer and the transparent electrode layer to improve the band gap discontinuity between the absorber layer and the transparent electrode layer.

The present invention also provides another thin film solar cell. The thin film solar cell comprises a substrate, a transparent electrode layer, a buffer layer, an absorber layer and a back electrode layer. These layers are formed on the substrate and deposited serially. The buffer layer is a compound consisting essentially of a metal and two different elements of Group VIA. The compound has a chemical formula of Mₓ(VIA1_{y}, VIA2_{z})_{w}. M represents a singular metal element or an alloy of multiple metal elements, and VIA1 and VIA2 are two different elements of Group VIA. X, y, z, w are non-zero positive numbers. The buffer layer has a band gap gradient between the absorber layer and the transparent electrode layer.

Therefore, another object of the present invention is to provide a thin film solar cell which has a buffer layer. The buffer layer is a compound which is essentially consisted of a metal and two different elements of Group VIA. The buffer layer has a band gap gradient between the absorber layer and the transparent electrode layer and the wavelength range of light utilized by the thin film solar cell is widened.

Still another object of the present invention is to provide a thin film solar cell which has a buffer layer. The buffer layer is a compound which is essentially consisted of a metal and two different elements of Group VIA. A band gap gradient is formed between the absorber layer and the transparent electrode layer to improve the band gap discontinuity between the absorber layer and the transparent electrode layer.

The present invention further provides a manufacturing method of a thin film solar cell. The manufacturing method comprises following steps:

(1) providing a substrate;

(2) forming a back electrode layer on the substrate;

(3) forming an absorber layer on the back electrode layer;

(4) forming a buffer layer on the absorber layer. The buffer layer is a compound consisted essentially of a metal and at least two elements of Group VIA, and the compound has a chemical formula: Mₓ(VIA1_{y}, VIA2_{z})_{w}, wherein M represents a singular metal element or an alloy of multiple metal elements, VIA1 and VIA2 are two different elements of Group VIA, and x, y, z, w are non-zero positive numbers.

(5) forming a transparent electrode layer on the buffer layer. Thereby, the buffer layer has a band gap gradient between the absorber layer and the transparent electrode layer.

Therefore, another object of the present invention is to provide a manufacturing method of a thin film solar cell which has a buffer layer. The buffer layer is a compound which is essentially consisted of a metal and two different elements of Group VIA. The buffer layer has a band gap gradient between the absorber layer and the transparent electrode layer and the wavelength range of light utilized by the thin film solar cell is widened.

Still another object of the present invention is to provide a manufacturing method of a thin film solar cell which has a buffer layer. The buffer layer is a compound which is essentially consisted of a metal and two different elements of Group VIA. The buffer layer has a band gap gradient between the absorber layer and the transparent electrode layer to improve the band gap discontinuity between the absorber layer and the transparent electrode layer.

The present invention still further provides a manufacturing method of a thin film solar cell. The manufacturing method comprises following steps:

(1) providing a substrate;

(2) forming a transparent electrode layer on the substrate;

(3) forming a buffer layer on the transparent electrode layer. The buffer layer is a compound consisted essentially of a metal and at least two elements of Group VIA, and the compound has a chemical formula: Mₓ(VIA1_{y}, VIA2_{z})_{w}, wherein M represents a singular metal element or an alloy of multiple metal elements, VIA1 and VIA2 are two different elements of Group VIA, and x, y, z, w are non-zero positive numbers.

(4) forming an absorber layer on the buffer layer. Thereby, the buffer layer has a band gap gradient between the absorber layer and the transparent electrode layer.

(5) forming a back electrode layer on the absorber layer.

Therefore, yet another object of the present invention is to provide a manufacturing method of a thin film solar cell which has a buffer layer. The buffer layer is a compound which is essentially consisted of a metal and two different elements of Group VIA. The buffer layer has a band gap gradient between the absorber layer and the transparent electrode layer and the wavelength range of light utilized by the thin film solar cell is widened.

Yet still another object of the present invention is to provide a manufacturing method of a thin film solar cell which has a buffer layer. The buffer layer is a compound which is essentially consisted of a metal and two different elements of Group VIA. The buffer layer has a band gap gradient between the absorber layer and the transparent electrode layer to improve the band gap discontinuity between the absorber layer and the transparent electrode layer.

### BRIEF DESCRIPTION OF THE DRAWINGS

The invention as well as a preferred mode of use, further objects and advantages thereof, will best be understood by reference to the following detailed description of an illustrative embodiment when read in conjunction with the accompanying drawings, wherein:

FIG. 1 is a side view of a thin film solar cell of the first embodiment of the present invention.

FIG. 2 is a side view of another thin film solar cell that is the second embodiment of the present invention.

### DETAILED DESCRIPTION OF THE PREFERRED EMBODIMENT

Some particular embodiments of the invention will be described in detail for purpose of illustration, and one of ordinary skill in the art can easily understand the advantages and efficacy of the present invention through the disclosure of the specification. It is to be understood that alternative embodiments may be possible for the implement and application of the present invention while numerous variations will be possible to the details disclosed in the specification on the strength of diverse concepts and applications without going outside the scope of the invention as disclosed in the claims.

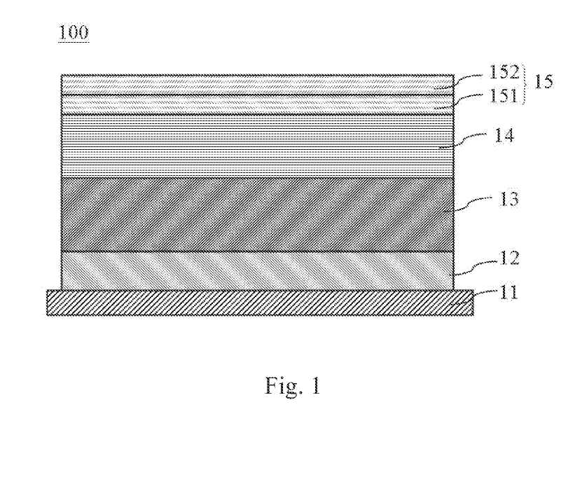

Please refer FIG. 1. The first embodiment of the present invention is a thin film solar cell 100. The thin film solar cell 100 comprises a substrate 11, a back electrode layer 12, an absorber layer 13, a buffer layer 14 and a transparent electrode layer 15. These layers 12, 13, 14, and 15 are formed on the substrate 11 and deposited serially. The transparent electrode 15 used here is multilayered and comprises a first transparent electrode layer 151 and a second transparent electrode layer 152. The buffer layer 14 is formed by a compound that is consisted essentially of a metal and two different elements of Group VIA. The compound has a chemical formula: Mₓ(VIA1_{y}, VIA2_{z})_{w}. M represents a singular metal element or an alloy of multiple metal elements, and VIA1 and VIA2 are two different elements of Group VIA. X, y, z, w are non-zero positive numbers. Thereby, the buffer layer 14 has a band gap gradient ranging from 1.6 eV to 4.0 eV between the absorber layer 13 and the transparent electrode layer 15.

The above-mentioned elements of Group VIA can be oxygen (O), sulfur (S), selenium (Se), or tellurium (Te). The singular metal mentioned above can be cadmium (Cd), zinc (Zn), indium (In), tin (Sn), or magnesium (Mg), and the alloy of multiple metal elements can be zinc magnesium (ZnMg), zinc indium (ZnIn), cadmium zinc (CdZn), zinc tin (ZnSn), or tin cadmium (CdSn). In addition, the buffer layer 14 is preferably deposited by the chemical bath deposition method from a first precursor comprising zinc, a second precursor comprising selenium and a third precursor comprising sulfur. More detailed, a solution comprising the above-mentioned three precursors is prepared and ammonium is added to be the complexing agent. The solution is kept at an adequate temperature. A semi-manufactured product comprising the substrate 11, back electrode layer 12, and the absorber layer 13 previously prepared (i.e., a SLG/Mo/CIGS product) is put into the solution mentioned above and a Zn(S, Se) layer (the buffer layer) will be deposited on the semi-manufactured product. In the process of the deposition, the difference in concentration of the sulfur precursor and the selenium precursor and the difference in solubility product of the zinc sulfide (ZnS) and the zinc selenide (ZnSe) together will make the deposition rates of the zinc sulfide and the zinc selenide different so that the deposited buffer layer is formed and has a concentration gradient of Zn(S,Se). Therefore, the band gap gradient buffer layer 14 is formed. In addition, the thickness of the buffer layer 14 ranges from 0.005 μm to 0.15 μm.

In the above-mentioned embodiment, the buffer layer 14 is a compound consisted essentially of a metal and two different elements of Group VIA as shown previously. Therefore, the buffer layer 14 has a band gap gradient between the absorber layer 13 and the transparent electrode layer 15 and the wavelength range of light utilized by the thin film solar cell 100 is therefore widened. For example, when the chemical formula of the compound is Zn(S,Se), it means that the buffer layer 14 is made by the zinc sulfide and the zinc selenide and has concentration gradients thereof. The band gap of the zinc sulfide is 3.8 eV and the band gap of the zinc selenide is 2.7 eV, so the band gap of Zn(S,Se) ranges from 2.7 eV to 3.8 eV. As described above, the buffer layer 14 has concentration gradients of Zn(S,Se). Therefore, the buffer layer 14 has a band gap gradient from 2.7 eV to 3.8 eV, and band gap discontinuity between the absorber layer 13 and the transparent electrode layer 15 is improved. Moreover, the buffer layer 14 of the present invention can be Zn(S,Se), In₂(S, Se)₃, or ZnIn(S,Se). The band gaps of those compounds have larger ranges than that of cadmium sulfide, so those compounds are good substitutions of the cadmium sulfide. The advantages of the substitution are to diminish the environment impact caused by cadmium and to widen the wavelength range of light utilized by the thin film solar cell.

The absorber layer 13 is deposited from the precursors of copper (Cu), indium (In), gallium (Ga), and selenium (Se), followed by selenization to form CIGS of chalcopyrite structure consisting of I-III-VI compounds. The element of Group I of the chalcopyrite structure can be copper (Cu). The element of Group III of the chalcopyrite structure can be aluminum (Al), indium (In), gallium (Ga), or the combination thereof. The element of Group VI of the chalcopyrite structure can be sulfur (S), selenium (Se), tellurium (Te), or the combination thereof. In addition, the thickness of the absorber layer 13 preferably ranges from 0.5 μm to 3.5 μm.

In this preferred embodiment, the material of the substrate 11 can be soda-lime glass (SLG), metal foil, or polyimide (PI). The transparent electrode layer 15 can be a single-layer or a multilayer (for example, the transparent electrode 151 and the transparent electrode layer 152) of a transparent conductive oxide (TCO), and the transparent conductive oxide can be tin oxide (SnO₂), indium tin oxide (ITO), zinc oxide (ZnO), aluminum zinc oxide (AZO), gallium zinc oxide (GZO) or indium zinc oxide (IZO). The transparent electrode layer 15 can be formed by sputtering or chemical vapor deposition (CVD). The back electrode layer 13 can be a single-layer or a multilayer structure. The back electrode layer 13 comprises a metal layer and the material of the metal layer can be molybdenum (Mo), silver (Ag), aluminum (Al), chromium (Cr), titanium (Ti), nickel (Ni), or gold (Au). In addition, the back electrode layer 13 can further comprise a transparent conductive oxide and the transparent conductive oxide can be tin oxide (SnO₂), indium tin oxide (ITO), zinc oxide (ZnO), aluminum zinc oxide (AZO), gallium zinc oxide (GZO) or indium zinc oxide (IZO). The back electrode layer 13 can be formed by sputtering or chemical vapor deposition.

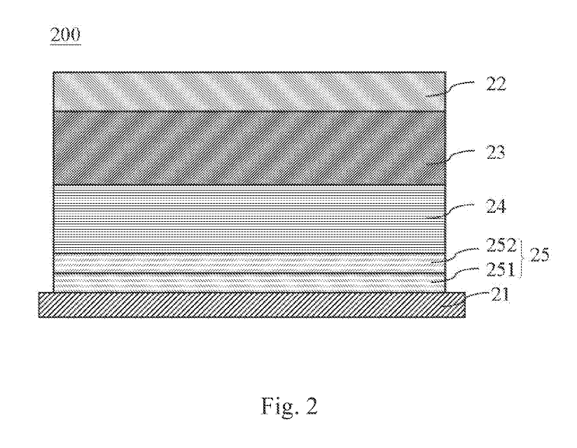

Please refer to FIG. 2. The second preferred embodiment of the present invention is another thin film solar cell 200. The thin film solar cell 200 comprises a substrate 21, a transparent electrode layer 25 (including a first transparent electrode layer 251 and the second transparent electrode layer 252), a buffer layer 24, an absorber layer 23 and a back electrode layer 22. These layers 25, 24, 23, and 22 are formed on the substrate 21 and deposited serially. The buffer layer 14 is formed by a compound that is consisted essentially of a metal and two different elements of Group VIA. The compound has a chemical formula: Mₓ(VIA1_{y}, VIA2_{z})_{w}. M represents a singular metal element or an alloy of multiple metal elements, and VIA1 and VIA2 are two different elements of Group VIA. X, y, z, w are non-zero positive numbers. Thereby, the buffer layer 24 has a band gap gradient ranging from 1.6 eV to 4.0 eV between the absorber layer 23 and the transparent electrode layer 25. The most obvious difference between the first embodiment and the second embodiment is that the stacking sequence of the first embodiment starts from the substrate 11, serially followed by the back electrode 12, the absorber layer 13, the buffer layer 14, and the transparent electrode layer 15 (including the first transparent layer 151 and the second transparent layer 152). However, the stacking sequence of the second embodiment starts from the substrate 21, serially followed by the transparent electrode layer 25 (including the first transparent layer 251 and the second transparent layer 252), the buffer layer 24, the absorber layer 23 and the back electrode layer 22. In addition, the substrate 21 is glass. Other characteristics and advantages of the thin film solar cell 200 of the second embodiment are substantially the same as those of the thin film solar cell 100 described in the first embodiment.

The present invention further provides a third embodiment. The third embodiment is a manufacturing method of the thin film solar cell 100. The manufacturing method includes the following steps and the numerical labels and their corresponding elements mentioned thereafter are depicted in FIG. 1.

(1) providing a substrate 11;

(2) forming a back electrode layer 12 on the substrate 11;

(3) forming an absorber layer 13 on the back electrode layer 12;

(4) forming a buffer layer 14 on the absorber layer 13. The buffer layer 14 is a compound consisted essentially of a metal and at least two elements of Group VIA, and the compound has a chemical formula: Mₓ(VIA1_{y}, VIA2_{z})_{w}, wherein M represents a singular metal element or an alloy of multiple metal elements, VIA1 and VIA2 are two different elements of Group VIA, and x, y, z, w are non-zero positive numbers.

(5) forming a transparent electrode layer 15 on the buffer layer 14. Thereby, the buffer layer 14 has a band gap gradient between the absorber layer 13 and the transparent electrode layer 15.

In the above-mentioned manufacturing method, the configurations, the structures, and the preferred materials of the substrate 11, the back electrode layer 12, the absorber layer 13, the buffer layer 14, and the transparent electrode layer 15 are substantially the same as those described in the first embodiment.

The present invention further provides a fourth embodiment. The fourth embodiment is a manufacturing method of another thin film solar cell 200. The manufacturing method includes the following steps and the numerical labels and their corresponding elements mentioned thereafter are depicted in FIG. 2.

(1) providing a substrate 21;

(2) forming a transparent electrode layer 25 on the substrate 21;

(3) forming a buffer layer 24 on the transparent electrode layer 25. The buffer layer 24 is a compound consisted essentially of a metal and at least two elements of Group VIA, and the compound has a chemical formula: Mₓ(VIA1_{y}, VIA2_{z})_{w}, wherein M represents a singular metal element or an alloy of multiple metal elements, VIA1 and VIA2 are two different elements of Group VIA, and x, y, z, w are non-zero positive numbers.

(4) forming an absorber layer 23 on the buffer layer 24. Thereby, the buffer layer 24 has a band gap gradient between the absorber layer 23 and the transparent electrode layer 25.

(5) forming a back electrode layer 22 on the absorber layer 23.

In the above-mentioned manufacturing method, the configurations, the structures, and the preferred materials of the substrate 21, the back electrode layer 22, the absorber layer 23, the buffer layer 24, and the transparent electrode layer 25 are substantially the same as those described in the second embodiment.

Although some particular embodiments of the invention have been described in detail for purposes of illustration, it will be understood by one of ordinary skill in the art that numerous variations will be possible to the disclosed embodiments without going outside the scope of the invention as disclosed in the claims.

What is claimed is:

1. A thin film solar cell comprising a substrate, a back electrode layer, an absorber layer, a buffer layer and a transparent electrode layer serially deposited, the thin film solar cell being characterized in that:
the buffer layer is a compound consisted essentially of a metal and at least two elements of Group VIA, and the compound has a chemical formula:
Mₓ(VIA1_{y},VIA2_{z})_{w},
wherein
M represents a singular metal element or an alloy of multiple metal elements,
VIA1 and VIA2 are two different elements of Group VIA, and
x, y, z, w are non-zero positive numbers,
whereby the buffer layer has a band gap gradient between the absorber layer and the transparent electrode layer.

2. The thin film solar cell of claim 1, wherein the band gap ranges from 1.6 eV to 4.0 eV.

3. The thin film solar cell of claim 1, wherein the metal is selected from the group consisting of cadmium (Cd), zinc (Zn), indium (In), tin (Sn), magnesium (Mg) and the combination thereof.

4. The thin film solar cell of claim 1, wherein the element of Group VIA is selected from the group consisting of oxygen (O), sulfur (S), selenium (Se), and tellurium (Te).

5. The thin film solar cell of claim 1, wherein the thickness of the buffer layer ranges from 0.005 μm to 0.15 μm.

6. The thin film solar cell of claim 1, wherein the buffer layer is made by the chemical bath deposition from a first precursor comprising zinc, a second precursor comprising selenium and a third precursor comprising sulfur.

7. The thin film solar cell of claim 1, wherein the absorber layer has a chalcopyrite structure consisting of a I-III-VI compound, and the Group I element of the chalcopyrite structure is copper (Cu), the Group III element of the chalcopyrite structure is selected from the group consisting of aluminum (Al), indium (In), gallium (Ga) and the combination thereof, and the Group VI element of the chalcopyrite structure is selected from the group consisting of sulfur (S), selenium (Se), tellurium (Te) and the combination thereof.

8. The thin film solar cell of claim 1, wherein the absorber layer is a CIGS layer and the thickness of the absorber layer ranges from 0.5 μm to 3.5 μm.

9. The thin film solar cell of claim 1, wherein the back electrode layer further comprises a metal layer and the material of the metal layer is selected from the group consisting of molybdenum (Mo), silver (Ag), aluminum (Al), chromium (Cr), titanium (Ti), nickel (Ni), and gold (Au), and also the back electrode layer and the transparent electrode comprises a transparent conductive oxide and the material of the transparent conductive oxide is selected from the group consisting of tin oxide (SnO₂), indium tin oxide (ITO), zinc oxide (ZnO), aluminum zinc oxide (AZO), gallium zinc oxide (GZO), and indium zinc oxide (IZO).

10. A thin film solar cell comprising a substrate, a transparent electrode layer, a buffer layer, an absorber layer and a back electrode layer serially deposited, the thin film solar cell being characterized in that:
the buffer layer is a compound consisted essentially of a metal and at least two elements of Group VIA, and the compound has a chemical formula:
Mₓ(VIA1_{y},VIA2_{z})_{w},
wherein
M represents a singular metal element or an alloy of multiple metal elements,
VIA1 and VIA2 are two different elements of Group VIA, and
x, y, z, w are non-zero positive numbers,
whereby the buffer layer has a band gap gradient between the absorber layer and the transparent electrode layer.

11. A manufacturing method of a thin film solar cell, comprising the steps:
providing a substrate;
forming a back electrode layer on the substrate;
forming an absorber layer on the back electrode layer;
forming a buffer layer on the absorber layer, the buffer layer being a compound consisted essentially of a metal and at least two elements of Group VIA, and the compound has a chemical formula: Mₓ (VIA1_{y}, VIA2_{z})_{w}, wherein M represents a singular metal element or an alloy of multiple metal elements, VIA1 and VIA2 are two different elements of Group VIA, and x, y, z, w are non-zero positive numbers; and
forming a transparent electrode layer on the buffer layer, whereby the buffer layer has a band gap gradient between the absorber layer and the transparent electrode layer.

12. The manufacturing method of a thin film solar cell of claim 11, wherein the band gap ranges from 1.6 eV to 4.0 eV.

13. The manufacturing method of a thin film solar cell of claim 11, wherein the metal is selected from the group consisting of cadmium (Cd), zinc (Zn), indium (In), tin (Sn), magnesium (Mg) and the combination thereof.

14. The manufacturing method of a thin film solar cell of claim 11, wherein the element of Group VIA is selected from the group consisting of oxygen (O), sulfur (S), selenium (Se), and tellurium (Te).

15. The manufacturing method of a thin film solar cell of claim 11, wherein the thickness of the buffer layer ranges from 0.005 μm to 0.15 μm.

16. The manufacturing method of a thin film solar cell of claim 11, wherein the buffer layer is made by the chemical bath deposition from a first precursor comprising zinc and a second precursor comprising selenium and sulfur.

17. The manufacturing method of a thin film solar cell of claim 11, wherein the absorber layer has a chalcopyrite structure consisting of a I-III-VI compound, and the Group I element of the I-III-VI compound is copper (Cu), the Group III element of the I-III-VI compound is selected from the group consisting of aluminum (Al), indium (In), gallium (Ga) and the combination thereof, and the Group VI element of the I-III-VI compound is selected from the group consisting of sulfur (S), selenium (Se), tellurium (Te) and the combination thereof.

18. The manufacturing method of a thin film solar cell of claim 11, wherein the absorber layer is a CIGS layer and the thickness of the absorber layer ranges from 0.5 μm to 3.5 μm.

19. The manufacturing method of a thin film solar cell of claim 11, wherein the back electrode layer further comprises a metal layer and the material of the metal layer is selected from the group consisting of molybdenum (Mo), silver (Ag), aluminum (Al), chromium (Cr), titanium (Ti), nickel (Ni), and gold (Au), and also the back electrode layer and the transparent electrode comprise a transparent conductive oxide and the material of the transparent conductive oxide is selected from the group consisting of tin oxide (SnO₂), indium tin oxide (ITO), zinc oxide (ZnO), aluminum zinc oxide (AZO), gallium zinc oxide (GZO), and indium zinc oxide (IZO).

20. A manufacturing method of a thin film solar cell, comprising the steps:
providing a substrate;
forming a transparent electrode layer on the substrate;
forming a buffer layer on the transparent electrode layer, the buffer layer being a compound consisted essentially of a metal and at least two elements of Group VIA, and the compound has a chemical formula: Mₓ (VIA1_{y}, VIA2_{z})_{w}, wherein M represents a singular metal element or an alloy of multiple metal elements, VIA1 and VIA2 are two different elements of Group VIA, and x, y, z, w are non-zero positive numbers;
forming an absorber layer on the buffer layer, whereby the buffer layer has a band gap gradient between the absorber layer and the transparent electrode layer; and
forming a back electrode layer on the absorber layer.
